(19) United States
(12) Patent Application Publication
(10) Pub. No.: US 2010/0009476 A1
(43) Pub. Date: Jan. 14, 2010

(54) SUBSTRATE STRUCTURE AND METHOD OF REMOVING THE SUBSTRATE STRUCTURE

(75) Inventors: Po Min TU, Chiayi County (TW); Shih Cheng HUANG, Hsinchu City (TW); Shih Hsiung CHAN, Hsinchu County (TW)

Correspondence Address: WPAT, PC;INTELLECTUAL PROPERTY ATTORNEYS, 2030 MAIN STREET, SUITE 1300, IRVINE, CA, 92614, US

(73) Assignee: ADVANCED OPTOELECTRONIC TECHNOLOGY INC., HSINCHU COUNTY (TW)

(21) Appl. No.: 12/501,333

(22) Filed: Jul. 10, 2009

(30) Foreign Application Priority Data
Jul. 14, 2008 (TW) 097126588

(51) Int. Cl. H01L 33/00; H01L 21/205

(52) U.S. Cl. 438/29; 438/492; 257/E21.101; 257/E33.068; 977/755

(57) ABSTRACT

A method of removing a substrate structure is described. A plurality of pillars is formed on a substrate by using a photolithography etching process. A group III nitride semiconductor layer is grown on the plurality of pillars. The plurality of pillars is etched to separate the group III nitride semiconductor layer from the substrate by using a chemical etching process.

### BACKGROUND OF THE INVENTION

1. Field of the Invention

The present invention relates to a semiconductor process, and more particularly, to a method for removing a substrate structure.

2. Description of the Related Art

Several prior arts disclose how to remove a substrate. For example, U.S. Pat. No. 6,648,966 and U.S. Pat. No. 7,169,227 respectively disclose methods for making a GaN wafer, wherein a material of the substrate is LiAlO₂. The thickness of the substrate is about 430 μm. The substrate is completely removed by using a wet etching process for several days (the acid etching rate for LiAlO₂ is about 15-30 nm/minute at room temperature). The efficiency of the above-mentioned process is low. In addition, removal of the substrate with only the wet etching process incurs a non-uniformity problem.

Moreover, U.S. Pat. No. 6,218,280 discloses that a LiAlO₂ substrate is peeled off by the application of mechanical force. However, the yield rate of this method is low and the LiAlO₂ substrate is too fragile to use this method. U.S. Pat. No. 6,218,280 also discloses that a substrate is removed merely with the wet etching process. Accordingly, this method also incurs low efficiency of removing substrates and non-uniformity problems.

In addition, methods for removing substrates disclosed by U.S. patent Publication No. 2007/0141814 includes a pure wet etching method, a dry etching method, a mechanical polishing method and a chemical mechanical polishing method. These methods all lead to problems of low removal efficiency, non-uniformity, or fragility.

U.S. Pat. No. 6,740,604 discloses a vertical light emitting device. A laser is used for irradiating the interface boundary between a substrate and an element layer to separate the substrate. Such devices for separating are expensive. In addition, warpage problems are caused due to thicker epitaxy layers.

U.S. Pat. No. 6,071,795 discloses a method for separating a substrate from a GaN layer with a laser. A low-temperature buffer layer is formed between a substrate and a GaN layer to alleviate the lattice mismatch of them. Because the low-temperature buffer layer is the most fragile, the low-temperature buffer layer is split first while the substrate is irradiated by a laser, so as to separate the substrate from the GaN layer. Such devices for separating are expensive. In addition, warpage problems are caused due to thicker epitaxy layers.

Based on the above, a method for removing a substrate structure to overcome the drawbacks caused by the above-mentioned methods is needed.

### SUMMARY OF THE INVENTION

An aspect of the invention is to propose a method for removing a substrate structure to overcome the drawbacks caused by aforesaid conventional methods.

Another aspect of the invention is to propose a substrate structure which can be applied to realize the above-mentioned method for removing the substrate structure.

In order to achieve the above-mentioned objective, the invention discloses a method for removing a substrate structure, comprising the steps of: forming a plurality of pillars on a substrate by using a photolithography etching process; forming a group III nitride semiconductor device layer on the plurality of pillars; forming a metallic mirror layer on the group III nitride semiconductor device layer; forming a conductive layer on the metallic mirror layer; and etching the plurality of pillars to separate the group III nitride semiconductor device layer from the substrate by using a chemical etching process, and then obtaining a vertical light emitting device, wherein the vertical light emitting device includes the group III nitride semiconductor device layer, the metallic mirror layer and the conductive layer.

This invention utilizes spaces between a plurality of pillars to substantially increase reaction areas for etching. Therefore, by using the method of the invention the efficiency of an etching process to separate a semiconductor layer from a substrate can be increased and the cost for a process can be reduced.

The invention also discloses a substrate structure comprising a substrate and a plurality of pillars. The plurality of pillars is formed on a substrate by using a photolithography etching process. A group III nitride semiconductor layer is formed on the plurality of pillars.

### BRIEF DESCRIPTION OF THE DRAWINGS

The invention will be described according to the appended drawings in which:

FIG. 1 is a flowchart of a method for removing a substrate structure in accordance with the first preferred embodiment of the present invention;

FIG. 2 is a flowchart of a method for removing a substrate structure in accordance with the second preferred embodiment of the present invention;

FIG. 3A and FIG. 3B include a diagram of each cross-sectional structure during the process indicated by the flowchart in FIG. 1;

FIG. 3A and FIG. 3C include the diagram of each cross-sectional structure during the process indicated by the flowchart in FIG. 2; and

FIG. 4 illustrates a diagram of radiation of a vertical light emitting device in accordance with FIG. 3C.

### PREFERRED EMBODIMENT OF THE PRESENT INVENTION

A semiconductor process is described in accordance with the present invention. Detailed structural elements are described as follows to realize this invention thoroughly. The embodiments of the present invention do not limit the details that are familiar to persons skilled in the light source module fields. On the other hand, well known elements are not described in detail to prevent the introduction of unnecessary limitations. Preferred embodiments are described in detail as follows. In addition to these detailed descriptions, this invention can also be implemented in a wide range of other embodiments. Furthermore, the scope of the present invention is not to be taken in a limiting sense, and is defined only by the appended claims.

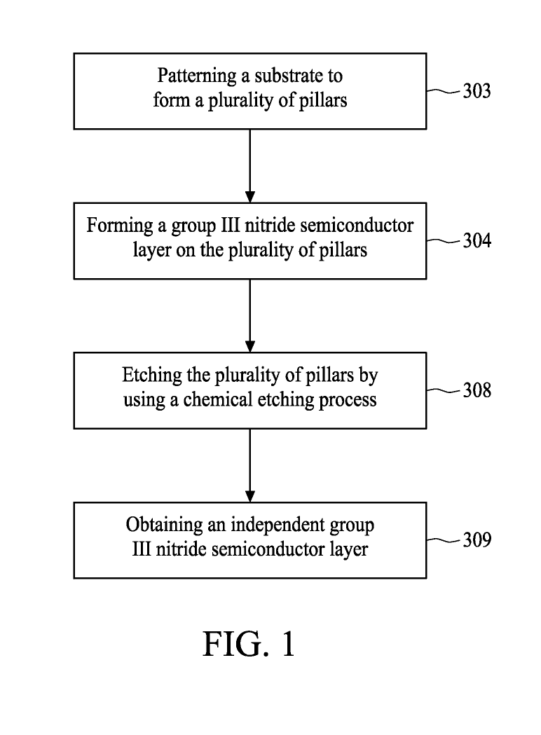

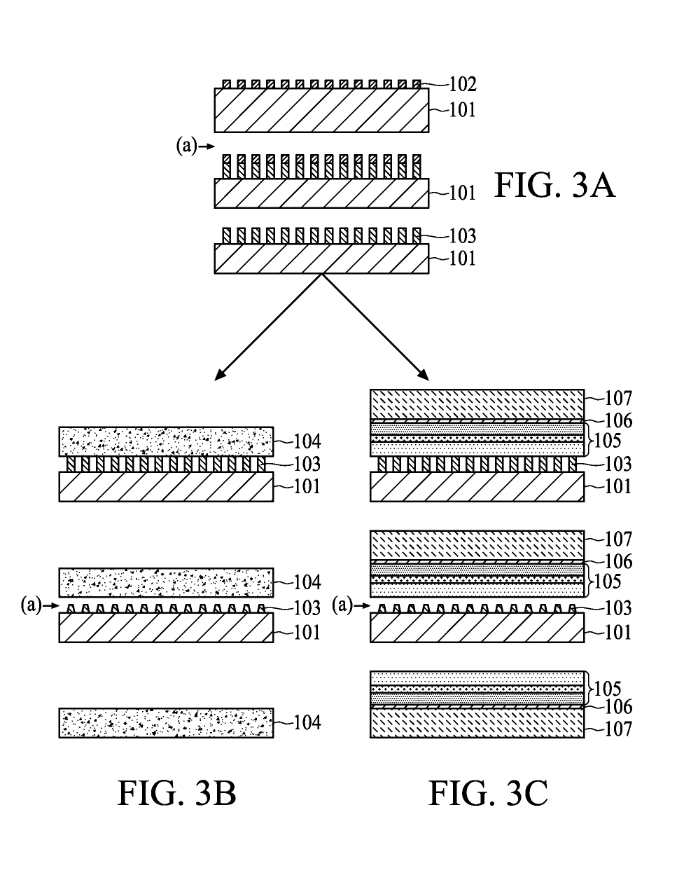

FIG. 1 illustrates a flowchart of a method for removing a substrate structure in accordance with the first preferred embodiment of the present invention. FIG. 3A and FIG. 3B illustrate the diagram of each cross-sectional structure during the process indicated by the flowchart in FIG. 1. Please refer to FIG. 3A and FIG. 1. In step 303, a plurality of pillars 103 are formed on a substrate 101 by using a photolithography etching process. This is also the step for patterning the substrate 101. The structure of the pillars shown herein is merely an example. Any geometric shape used for increasing the surface area of the substrate 101 would not depart from the spirit and the scope of the invention. A material of the substrate 101 can be LiAlO₂ or LiGaO₂.

As shown in FIG. 3A, a mask 102 on the substrate 101. After etching with the above-mentioned photolithography etching process, the plurality of pillars 103 is formed. Next, the mask 102 is removed.

As shown in FIG. 1 and FIG. 3B, in step 304, a group III nitride semiconductor layer 104 is grown on the plurality of pillars 103. The group III nitride semiconductor layer 104 can be a gallium nitride layer, an aluminum nitride layer, an indium nitride layer or an aluminum gallium indium nitride layer. A process for forming the group III nitride semiconductor layer 104 can be a hydride vapor phase epitaxy (HVPE) process, a metal organic chemical vapor phase deposition (MOCVD) process or a molecular beam epitaxy (MBE) process.

In step S308, by using a chemical etching process the plurality of pillars 103 is etched to separate the group III nitride semiconductor layer 104 from the substrate 101, so as to obtain an independent group III nitride semiconductor layer 104 (step S309). The chemical etching process immerses the entire structures of the substrate 101, the plurality of pillars 103 and the group III nitride semiconductor layer 104 in etching solution (a). The etching solution (a) can be aqueous sulfuric acid, phosphoric acid, hydrochloric acid, or combination thereof (for example, the aqueous sulfuric acid may be added to the phosphoric acid). At this time, because a wet etching process is an anisotropic etching process, the etching solution (a) flows transversely into spaces between the plurality of pillars 103. During the etching process, because the pillars 103 are quite thin, the plurality of pillars 103 is broken first to separate the group III nitride semiconductor layer 104 from the substrate 101. After the etching process, the plurality of pillars 103 may remain on the group III nitride semiconductor layer 104 and on the substrate 101.

If the group III nitride semiconductor layer 104 is formed on the substrate 101 without the plurality of pillars 103, the etching process with the etching solution (A) requires a lengthy etching time to separate the substrate 101 from the group III nitride semiconductor layer 104.

This invention utilizes spaces between the plurality of pillars to substantially increase reaction areas for etching. Therefore, with the method of the invention the efficiency of the etching process to separate a semiconductor layer from a substrate can be increased and the cost of the process can be reduced to obtain an independent group III nitride semiconductor substrate.

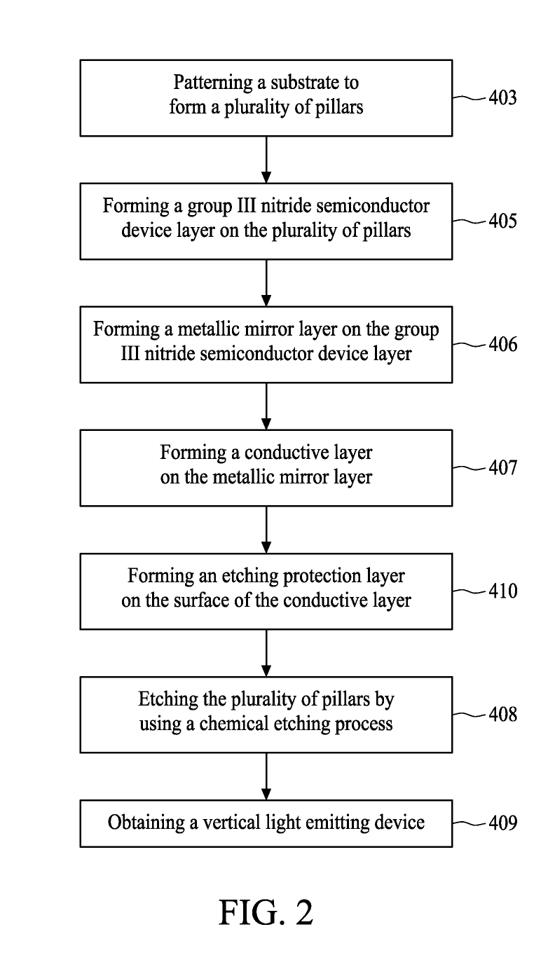

FIG. 2 illustrates a flowchart of a method for removing a substrate structure in accordance with the second preferred embodiment of the present invention. FIG. 3A and FIG. 3C illustrate the diagram of each cross-sectional structure during the process indicated by the flowchart in FIG. 2. As shown in FIG. 3A and FIG. 2, in step 403, the plurality of pillars 103 is formed on the substrate 101 by using the photolithography etching process. This is also the step for patterning the substrate 101. The structure of the pillars shown herein is merely an example. Any geometric shape used for increasing the surface area of the substrate 101 would not depart from the spirit and the scope of the invention. A material of the substrate can be LiAlO₂ or LiGaO₂.

Please refer to FIG. 3A, the mask 102 on the substrate 101. After etching with the above-mentioned photolithography etching process, the plurality of pillars 103 is formed. Next, the mask 102 is removed.

As shown in FIG. 2 and FIG. 3C, in step 405, a group III nitride semiconductor device layer 105 is grown on the plurality of pillars 103. The group III nitride semiconductor device layer 105 includes an n-type layer, a quantum well layer and a p-type layer.

In step S406, a metallic mirror layer 106 is formed on the group III nitride semiconductor device layer 105. A conductive layer 107 is formed on the metallic mirror layer 106. The process for forming the conductive layer 107 can be a deposition process, a chemical plating process, an electroplate process or a bonding process.

In step S408, by using a chemical etching process the plurality of pillars 103 is etched to separate the group III nitride semiconductor device layer 105 from the substrate 101, so as to obtain a vertical light emitting device (step S409). The chemical etching process immerses the entire structures of the substrate 101, the plurality of pillars 103, the group III nitride semiconductor device layer 105, the metallic mirror layer 106 and the conductive layer 107 in etching solution (a). The etching solution (a) can be aqueous sulfuric acid, phosphoric acid, hydrochloric acid, or combination thereof (for example, the aqueous sulfuric acid may be added to the phosphoric acid). At this time, because the wet etching process is an anisotropic etching process, the etching solution (a) flows transversely into spaces between the plurality of pillars 103. During the etching process, because the pillars 103 are quite thin, the plurality of pillars 103 is broken first to separate the group III nitride semiconductor device layer 105 from the substrate 101. After the etching process, the plurality of pillars 103 may remain on the group III nitride semiconductor layer 104 and on the substrate 101.

If the group III nitride semiconductor device layer 105, the metallic mirror layer 106 and the conductive layer 107 are formed on the substrate 101 without the plurality of pillars 103, the etching process with the etching solution (A) requires a lengthy etching time to separate the substrate 101 from the group III nitride semiconductor device layer 105.

This invention utilizes spaces between a plurality of pillars to substantially increase reaction areas for etching. Therefore, by using the method of the invention the efficiency of the etching process to separate a semiconductor layer from a substrate can be increased and the cost for a process can be reduced.

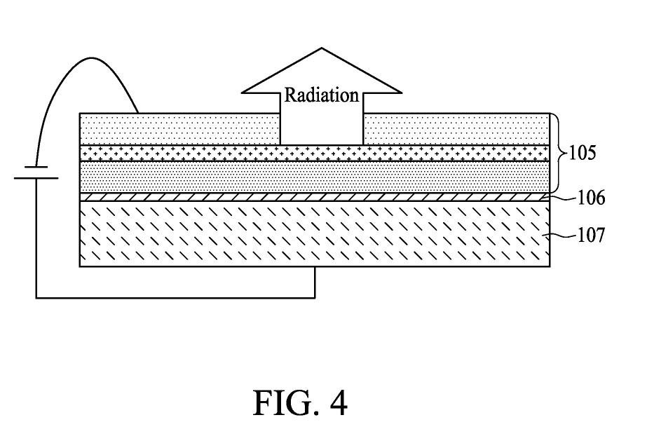

FIG. 4 illustrates a diagram of radiation of a vertical light emitting device in accordance with FIG. 3C. In FIG. 4 and FIG. 3C together, the above-mentioned group III nitride semiconductor device layer 105 is placed upside down. From top to bottom the vertical light emitting device can include the group III nitride semiconductor device layer 105, the metallic mirror layer 106 and the conductive layer 107.

As shown in FIG. 3C and FIG. 2, before etching the plurality of pillars 103, an etching protection layer can be formed on the surface of the conductive layer 107 (step S410). However, this step can be omitted. In contrast to the conductive layer 107, the plurality of pillars 103 are fragile. In an environment with vapor, the plurality of pillars 103 may be etched. This situation is a phenomenon of deliquesce.

For example, the oxygen atoms of the LiAlO₂ material used for the plurality of pillars 103 combine easily with water so that bonds of the LiAlO₂ are easily broken. Etching solution generally includes water so that the plurality of pillars 103 is etched easily. Accordingly, even without a protection layer, an obtained vertical light emitting device can be etched slightly (possible to a depth of several microns). The quantum well layer in the obtained vertical light emitting device will not be damaged. Because the thickness of the conductive layer 107 is relatively thick, the etched thickness is relatively thin.

Comparatively, the thickness of the plurality of pillars 103 can be about 3-4 microns. Because there are spaces between the plurality of pillars 103, the etching solution (a) flows into the spaces between the plurality of pillars 103. The plurality of pillars 103 are separated from the group III nitride semiconductor device layer 105 in only a few minutes.

This invention offers at least the following advantages:
1. This invention utilizes spaces between a plurality of pillars to substantially increase reaction areas for etching. Therefore, by using the method of the invention the efficiency of an etching process to separate a semiconductor layer from a substrate can be increased and the process cost can be reduced.
2. A substrate can be separated quickly and with a high degree of uniformity. Any post-process of chemical mechanical polishing or over etching process is not required.
3. Expensive laser separation equipment is not required. Substrates can be retrieved and recycled so that the cost can be reduced.
4. By using this invention, the etching process is implemented easily and without high temperatures, so that damage to the group III nitride semiconductor layer can be reduced. The acid etching rate is generally about 30 nm/minute at room temperature. For example, for a substrate with the thickness of 430 μm, several days are needed when using conventional methods for etching the substrate completely. If the etching rate is increased by increasing temperature, the group III nitride semiconductor layer will be damaged. Thus, methods with lower temperatures are preferred.

The above-described embodiments of the present invention are intended to be illustrative only. Numerous alternative embodiments may be devised by persons skilled in the art without departing from the scope of the following claims.

What is claimed is:

1. A method for removing a substrate structure, comprising the steps of:
forming a plurality of pillars on a substrate by using a photolithography etching process;
forming a group III nitride semiconductor layer on the plurality of pillars; and
etching the plurality of pillars to separate the group III nitride semiconductor layer from the substrate by using a chemical etching process.

2. The method for removing a substrate structure according to claim 1, wherein a process for forming the group III nitride semiconductor layer is a hydride vapor phase epitaxy (HVPE) process, a metal organic chemical vapor phase deposition (MOCVD) process or a molecular beam epitaxy (MBE) process.

3. The method for removing a substrate structure according to claim 1, wherein the step of etching the plurality of pillars by using the chemical etching process uses etching solution.

4. The method for removing a substrate structure according to claim 3, wherein the etching solution is aqueous sulfuric acid, phosphoric acid, hydrochloric acid, or combination thereof.

5. The method for removing a substrate structure according to claim 1, wherein the group III nitride semiconductor layer is a gallium nitride layer, an aluminum nitride layer, an indium nitride layer or an aluminum gallium indium nitride layer.

6. The method for removing a substrate structure according to claim 1, wherein a material of the substrate is LiAlO₂ or LiGaO₂.

7. The method for removing a substrate structure according to claim 6, wherein the substrate is a patterned substrate.

8. The method for removing a substrate structure according to claim 1, wherein the group III nitride semiconductor layer includes an n-type layer, a quantum well layer and a p-type layer.

9. A method for removing a substrate structure, comprising the steps of:
forming a plurality of pillars on a substrate by using a photolithography etching process;
forming a group III nitride semiconductor device layer on the plurality of pillars;
forming a metallic mirror layer on the group III nitride semiconductor device layer;
forming a conductive layer on the metallic mirror layer; and
etching the plurality of pillars to separate the group III nitride semiconductor device layer from the substrate by using a chemical etching process, and then obtaining a vertical light emitting device.

10. The method for removing a substrate structure according to claim 9, wherein the vertical light emitting device includes the group III nitride semiconductor device layer, the metallic mirror layer and the conductive layer.

11. The method for removing a substrate structure according to claim 9, wherein a process for forming the group III nitride semiconductor device layer is a hydride vapor phase epitaxy (HVPE) process, a metal organic chemical vapor phase deposition (MOCVD) process or a molecular beam epitaxy (MBE) process.

12. The method for removing a substrate structure according to claim 9, wherein the step of etching the plurality of pillars by using the chemical etching process uses etching solution.

13. The method for removing a substrate structure according to claim 12, wherein the etching solution is aqueous sulfuric acid, phosphoric acid, hydrochloric acid, or combination thereof.

14. The method for removing a substrate structure according to claim 9, wherein the group III nitride semiconductor layer is a gallium nitride layer, an aluminum nitride layer, an indium nitride layer or an aluminum gallium indium nitride layer.

15. The method for removing a substrate structure according to claim 9, wherein a material of the substrate is LiAlO₂ or LiGaO₂.

16. The method for removing a substrate structure according to claim 15, wherein the substrate is a patterned substrate.

17. The method for removing a substrate structure according to claim 9, wherein the group III nitride semiconductor layer includes an n-type layer, a quantum well layer and a p-type layer.
